(19) United States
(12) Patent Application Publication
(10) Pub. No.: US 2025/0364518 A1
(43) Pub. Date: Nov. 27, 2025

(54) INTEGRATED PACKAGE STRUCTURE WITH INDUCTOR AND INTEGRATED CIRCUIT AND MANUFACTURING METHOD THEREOF

(71) Applicant: Richtek Technology Corporation, Zhubei City (TW)

(72) Inventors: Shih-Chieh Lin, Kaohsiung (TW); Heng-Chi Huang, Hsinchu (TW); Lung-Sheng Lin, Hsinchu (TW); Chih-Feng Huang, Hsinchu (TW)

(21) Appl. No.: 19/008,724

(22) Filed: Jan. 3, 2025

Related U.S. Application Data
(60) Provisional application No. 63/650,428, filed on May 22, 2024.

(30) Foreign Application Priority Data
Dec. 9, 2024 (TW) 113147736

(51) Int. Cl. H01L 25/18; H01L 21/3105; H01L 21/48; H01L 21/56; H01L 23/00; H01L 23/31; H01L 23/367; H01L 23/498; H05K 1/18

(52) U.S. Cl. CPC H01L 25/18; H01L 21/31051; H01L 21/4875; H01L 21/563; H01L 21/565; H01L 23/3157; H01L 23/3672; H01L 24/16; H01L 24/32; H01L 24/73; H01L 23/49838; H01L 24/13; H01L 2224/13147; H01L 2224/16225; H01L 2224/16245; H01L 2224/32225; H01L 2224/32245; H01L 2224/32265; H01L 2224/73204; H01L 2224/73253; H01L 2924/1206; H05K 1/181

(57) ABSTRACT

The present invention provides an integrated package structure with an inductor and an integrated circuit and a manufacturing method thereof. The integrated package structure includes: a substrate with a predetermined circuit layout; an integrated circuit positioned on the substrate, wherein the integrated circuit is joined to the substrate in a flip-chip configuration, and a joint between the integrated circuit and the substrate is encapsulated by a covering material, with a back surface of the integrated circuit exposed; and an inductor, positioned above the integrated circuit, wherein a lower surface of the inductor is connected to the back surface of the integrated circuit, and at least a portion of a contact area between the inductor's lower surface and the back surface of the integrated circuit is free from encapsulation material.

### CROSS REFERENCE

The present invention claims priority to U.S. 63/650,428 filed on May 22, 2024, and claims priority to TW 113147736 filed on Dec. 9, 2024.

### BACKGROUND OF THE INVENTION

### Field of Invention

The present invention relates to an integrated package structure with an inductor and an integrated circuit (IC) and a manufacturing method thereof. In particular, it relates to such an integrated package structure in which at least a portion of a connection area between a lower surface of the inductor and a back surface of the integrated circuit is free from encapsulation material, as well as the manufacturing method of such an integrated package structure with an inductor and an integrated circuit.

### Description of Related Art

As shown in FIG. 1, a prior art integrated package structure 10 with an inductor and an integrated circuit includes a substrate 101, an integrated circuit 102, passive components 103, and an inductor 104. The integrated package structure 10 consists of discrete components, resulting in a larger overall size and footprint, which is not conducive to miniaturized designs.

Another prior art structure, as disclosed in U.S. Pat. No. 11,317,545, describes an integrated package structure with an inductor and an integrated circuit, in which the inductor is surrounded by a metal sheet to assist in dissipating heat from the integrated circuit beneath it. Additionally, a heatsink is placed above the inductor. However, this design has several drawbacks, including issues with the flatness of the connection surface between the metal sheet and the inductor. Furthermore, the need for thermal paste between the metal sheet and the inductor's magnetic material reduces the overall heat dissipation capacity. The heatsink above the inductor also connects to the uneven metal sheet via a thermal interface material (TIM). The low thermal conductivity of the TIM and the uneven spacing caused by the irregular metal sheet further degrade the heat dissipation efficiency.

In addition, designs involving stacked electronic components typically use encapsulation materials such as compound to protect the components from physical, chemical, or electrical interference. In power modules, passive components such as inductors and capacitors are often integrated with power switch integrated circuits (SPS ICs) to form buck modules. An ideal heat dissipation solution involves directly connecting the IC chip to a high thermal conductivity metal plate on the inductor. This approach not only saves space but also effectively enhances heat dissipation. However, this configuration may expose the IC to external metal plates, making it susceptible to external electrical potential interference and increasing the risk of burnout. For safety, ICs are generally protected with compound materials, though this compromises some heat dissipation efficiency.

In view of the aforementioned issues, the present invention provides an improved design. By utilizing encapsulation materials through molding or underfill to protect the sides and bottom of the IC chip while exposing the IC chip's back surface, better heat dissipation can be achieved. Furthermore, in the embodiments, high thermal conductivity metals are placed inside the inductor. Conductive magnetic alloy materials, with thermal conductivity of approximately 5-25 W/mK, are used for heat dissipation. These materials outperform encapsulation compounds used in molding (with thermal conductivity of approximately 1-3 W/mK) in terms of thermal performance and simultaneously possess insulation and heat dissipation characteristics, thereby reducing the risk of electrical leakage in various environmental conditions.

### SUMMARY OF THE INVENTION

From one perspective, the present invention provides an integrated package structure with an inductor and an integrated circuit, comprising: a substrate having a predetermined circuit layout; an integrated circuit positioned on the substrate, wherein the integrated circuit is joined to the substrate in a flip-chip configuration, and a joint between the integrated circuit and the substrate is encapsulated by a covering material, with a back surface of the integrated circuit exposed; and an inductor positioned above the integrated circuit, wherein a lower surface of the inductor is connected to the back surface of the integrated circuit, forming a connection area, and at least a portion of the connection area is free from encapsulation material.

In one embodiment, the integrated circuit undergoes molding, and the encapsulation material on a back surface of the integrated circuit is ground to expose the back surface.

In one embodiment, the integrated circuit undergoes underfill without molding, thereby exposing the back surface of the integrated circuit.

In one embodiment, the back surface of the integrated circuit is either non-backside metallized (non-BSM) or backside metallized (BSM).

In one embodiment, the substrate includes a lead frame or a printed circuit board (PCB).

In one embodiment, the magnetic material providing the inductance is selected from ceramic magnetic materials or metallic soft magnetic materials, including ceramic materials such as nickel-zinc ferrite, manganese-zinc ferrite, or magnesium-copper-zinc ferrite, or metallic soft magnetic materials such as carbonyl iron powder, iron-nickel alloys, iron-silicon alloys, iron-silicon-aluminum alloys, iron-silicon-chromium alloys, or amorphous alloys.

In one embodiment, the joint includes at least one metal pillar, at least one solder ball, or at least one copper-to-copper bond.

In one embodiment, the inductor is in a form selected from an exposed magnetic material or a metal-embedded configuration.

In one embodiment, when the inductor is in the form of an exposed magnetic material, the magnetic material providing inductance is connected to the back surface of the integrated circuit.

In one embodiment, when the inductor is in the form of a metal-embedded configuration, an outer-side magnetic material or a framework of the inductor is connected to the back surface of the integrated circuit.

In one embodiment, the lower surface of the inductor is connected to the back surface of the integrated circuit through a thermal interface material (TIM) or solder.

In one embodiment, a metal plate is positioned above the inductor, and the metal plate is connected to an upper surface of the inductor through a thermal interface material or solder.

In one embodiment, the back surface of the integrated circuit, partially or fully exposed, is connected to the lower surface of the inductor.

From another perspective, the present invention provides an integrated package structure with an inductor and an integrated circuit, comprising: a substrate having a predetermined circuit layout; an integrated circuit positioned on the substrate, wherein the integrated circuit is joined to the substrate in a flip-chip configuration, and a joint between the integrated circuit and the substrate is encapsulated by a covering material, with a back surface of the integrated circuit exposed; a metal plate positioned above the integrated circuit, wherein a lower surface of the metal plate is connected to the back surface of the integrated circuit, and at least a portion of a connection area between the lower surface of the metal plate and the back surface of the integrated circuit is free from encapsulation material; and an inductor positioned below the substrate and connected to the substrate.

From another perspective, the present invention provides a manufacturing method of an integrated package structure with an inductor and an integrated circuit, comprising: providing an integrated circuit; positioning the integrated circuit on a substrate and joining the integrated circuit to the substrate in a flip-chip configuration; after molding, grinding the encapsulation material on the back surface of the integrated circuit, or performing underfill without molding to expose a back surface of the integrated circuit; and positioning an inductor above the integrated circuit, wherein a lower surface of the inductor is connected to the back surface of the integrated circuit, forming a connection area, and at least a portion of the connection area is free from encapsulation material.

From another perspective, the present invention provides a manufacturing method of an integrated package structure with an inductor and an integrated circuit, comprising: providing an integrated circuit; positioning the integrated circuit on a substrate and joining the integrated circuit to the substrate in a flip-chip configuration; after molding, grinding the encapsulation material on the back surface of the integrated circuit, or performing underfill without molding to expose a back surface of the integrated circuit; positioning a metal plate above the integrated circuit, wherein a lower surface of the metal plate is connected to the back surface of the integrated circuit, forming a connection area, and at least a portion of the connection area is free from encapsulation material; and positioning an inductor below the substrate and connecting it to the substrate.

The objectives, technical details, features, and effects of the present invention will be better understood with regard to the detailed description of the embodiments below, with reference to the attached drawings.

### BRIEF DESCRIPTION OF THE DRAWINGS

FIG. 1 illustrates an integrated package structure 10 with an inductor and an integrated circuit of the prior art.

FIG. 2 is a cross-sectional schematic diagram showing an embodiment of an integrated package structure with an inductor and an integrated circuit according to the present invention.

FIG. 3 is a cross-sectional schematic diagram showing another embodiment of an integrated package structure with an inductor and an integrated circuit according to the present invention.

FIG. 4 is a cross-sectional schematic diagram showing yet another embodiment of an integrated package structure with an inductor and an integrated circuit according to the present invention.

FIG. 5 is a cross-sectional schematic diagram showing a further embodiment of an integrated package structure with an inductor and an integrated circuit according to the present invention.

FIG. 6 is a cross-sectional schematic diagram showing a variant embodiment of an integrated package structure with an inductor and an integrated circuit according to the present invention.

FIG. 7 is a cross-sectional schematic diagram showing an alternative embodiment of an integrated package structure with an inductor and an integrated circuit according to the present invention.

FIG. 8 is a cross-sectional schematic diagram showing another alternative embodiment of an integrated package structure with an inductor and an integrated circuit according to the present invention.

FIG. 9 is a cross-sectional schematic diagram showing a different embodiment of an integrated package structure with an inductor and an integrated circuit according to the present invention.

FIG. 10 is a cross-sectional schematic diagram showing yet another alternative embodiment of an integrated package structure with an inductor and an integrated circuit according to the present invention.

FIG. 11 is a cross-sectional schematic diagram showing an additional embodiment of an integrated package structure with an inductor and an integrated circuit according to the present invention.

FIG. 12 is a cross-sectional schematic diagram showing another embodiment of an integrated package structure with an inductor and an integrated circuit according to the present invention.

FIG. 13 is a cross-sectional schematic diagram showing a further embodiment of an integrated package structure with an inductor and an integrated circuit according to the present invention.

FIGS. 14A, 14B, and 14C are perspective schematic diagrams illustrating the manufacturing method of an integrated package structure with an inductor and an integrated circuit 50 according to the present invention.

FIGS. 15A, 15B, 15C, and 15D are cross-sectional schematic diagrams illustrating the manufacturing method of an integrated package structure with an inductor and an integrated circuit 110 according to the present invention.

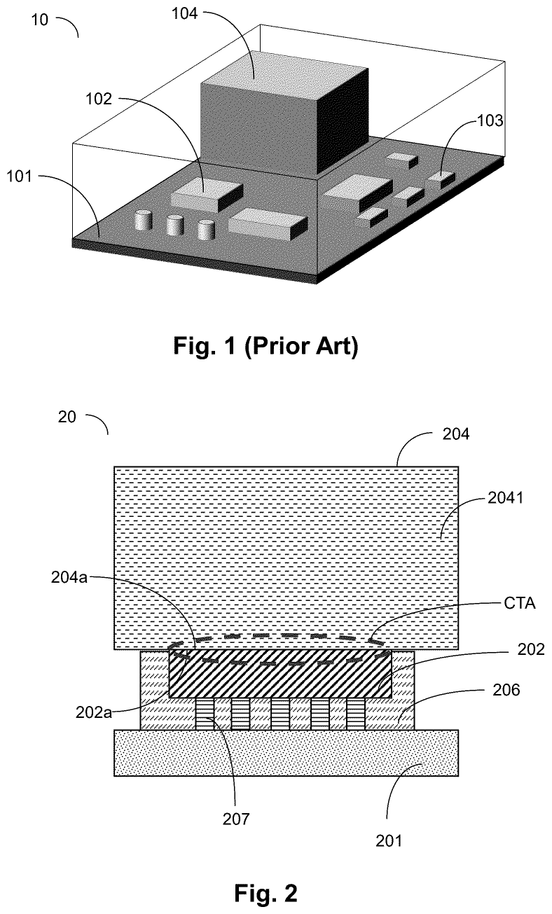

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

FIG. 2 is a cross-sectional schematic diagram of an integrated package structure with an inductor and an integrated circuit according to an embodiment of the present invention. As shown in FIG. 2, the integrated package structure 20 comprises a substrate 201, an integrated circuit 202, and an inductor 204. The substrate 201 has a predetermined circuit layout for mounting and connecting other electronic components. The substrate 201 may be a printed circuit board (PCB) or a lead frame and provides electrical signal transmission functionality, forming an electrical connection with the integrated circuit 202.

The integrated circuit 202 is mounted on the substrate 201 in a flip-chip manner, providing stable electrical connections and reducing impedance. The backside 202a of the integrated circuit 202 is partially or fully exposed after packaging to facilitate heat dissipation. The bonding material 207, which bonds the integrated circuit 202 to the substrate 201, is covered by an encapsulation material 206 for protection against external interference. The encapsulation material 206 can be applied using underfill or molding methods, but it does not cover at least a portion of the backside 202a of the integrated circuit, allowing it to remain exposed to enhance thermal conductivity. In this embodiment, molding is used, and after molding, the encapsulation material on the backside 202a of the integrated circuit 202 is ground to expose the backside.

The inductor 204 is disposed above the integrated circuit 202 and includes magnetic materials. The bottom surface 204a of the inductor is connected to the backside 202a of the integrated circuit, forming a connection area CTA. In the connection area CTA, at least a portion of it is free of encapsulation material, ensuring optimal heat dissipation performance. The magnetic material in the inductor 204 has a higher thermal conductivity compared to the encapsulation material, aiding in heat dissipation from the integrated circuit 202 while maintaining insulation to avoid electrical leakage.

According to the present invention, the integrated package structure 20 in this embodiment not only enhances the heat dissipation efficiency of the integrated circuit 202 but also reduces overall space requirements. The encapsulation material 206 is used only to protect the electrical connections on the sides and bottom of the integrated circuit 202, leaving the backside uncovered to maintain an open heat dissipation pathway and minimize thermal resistance introduced by using thermal interface materials or thermal paste.

As shown in FIG. 2, in one embodiment, the integrated package structure 20 of the present invention features improved heat dissipation characteristics. Specific technical features enhance the connection and heat dissipation performance between the inductor 204 and the integrated circuit 202. For example, the backside 202a of the integrated circuit 202 may be left as non-backside metallization (non-BSM) or processed with backside metallization (BSM) for enhanced thermal conduction or specific electrical connections, depending on heat dissipation and conduction requirements. This selective design allows the backside 202a of the integrated circuit 202 to be treated accordingly, further optimizing thermal and electrical performance.

In one embodiment, the magnetic material providing inductance in the inductor 204 may consist of ceramic magnetic materials or metal soft magnetic materials. Specifically, the magnetic material may include ceramic materials such as nickel-zinc ferrite, manganese-zinc ferrite, or magnesium-copper-zinc ferrite, or metal soft magnetic materials such as carbon-based iron powder, iron-nickel alloys, iron-silicon alloys, iron-silicon-aluminum alloys, iron-silicon-chromium alloys, or amorphous alloys. These magnetic materials not only possess higher thermal conductivity for improved heat dissipation but also have insulating properties to protect the integrated circuit 202 from electrical interference.

The bonding material 207 between the integrated circuit 202 and the substrate 201 may include at least one metal pillar, at least one solder ball, or at least one copper-copper bond. These bonding methods provide stable electrical and mechanical connections between the integrated circuit 202 and the substrate 201, balancing electrical connection strength and thermal conductivity according to packaging structure requirements. This design ensures stable connections and achieves excellent conductivity and heat dissipation.

The structure of the inductor 204 may adopt different configurations, such as exposed magnetic materials, metal-encased designs, or metal-embedded designs. In the embodiment shown in FIG. 2, the inductor 204 employs an exposed magnetic material configuration, where the magnetic material 2041 is exposed at the bottom surface 204a of the inductor and connected to the backside 202a of the integrated circuit, forming the connection area CTA. At least a portion of the connection area CTA is free of encapsulation material, ensuring optimal thermal performance. This direct connection design effectively enhances the thermal conductivity between the inductor 204 and the integrated circuit 202, resulting in superior heat dissipation performance.

In one embodiment, the bottom surface 204a of the inductor can be connected to the backside 202a of the integrated circuit using thermal interface material (TIM) or solder. The thermal interface material provides an efficient thermal transfer pathway while ensuring stable connections between the inductor 204 and the integrated circuit 202, reducing thermal resistance and enhancing heat dissipation efficiency. This design achieves optimal thermal performance while maintaining connection stability.

In one embodiment, the backside 202a of the integrated circuit 202 can be partially or fully exposed to facilitate connection with the bottom surface 204a of the inductor. By exposing the backside 202a of the integrated circuit 202, the present invention can effectively enhance heat dissipation efficiency and reduce thermal resistance caused by encapsulation material or other materials. This design ensures an open thermal pathway and significantly improves the performance of the integrated circuit 202 in high heat dissipation applications.

FIG. 3 illustrates another embodiment of an integrated package structure 30 with an inductor and an integrated circuit according to the present invention. The primary difference between this embodiment and the embodiment shown in FIG. 2 lies in the packaging method for the integrated circuit 202.

In the embodiment shown in FIG. 3, the integrated circuit 202 is mounted on the substrate 201 in a flip-chip manner, providing stable electrical connections and reducing impedance. Unlike the embodiment in FIG. 2, this embodiment adopts an underfill method instead of molding. The underfill encapsulation material 206 fills the gap between the integrated circuit 202 and the substrate 201, enhancing mechanical strength and providing protection but leaving the backside 202a of the integrated circuit 202 uncovered to facilitate thermal conductivity.

Through the above configurations and variations, the preferred embodiments of the present invention enable efficient thermal management and electrical stability in high-density electronic applications, ensuring reliable operation under demanding conditions.

In this embodiment, the underfill encapsulation provides protection for the sides and bottom of the integrated circuit 202 while allowing the backside to remain exposed for maximum thermal performance. This design further enhances the heat dissipation efficiency of the integrated package structure 30 and reduces the volume typically associated with molding, making the overall structure more compact and high-performing. This configuration offers advantages in effective heat dissipation, structural stability, and space utilization, suitable for high power density and miniaturized electronic packaging applications.

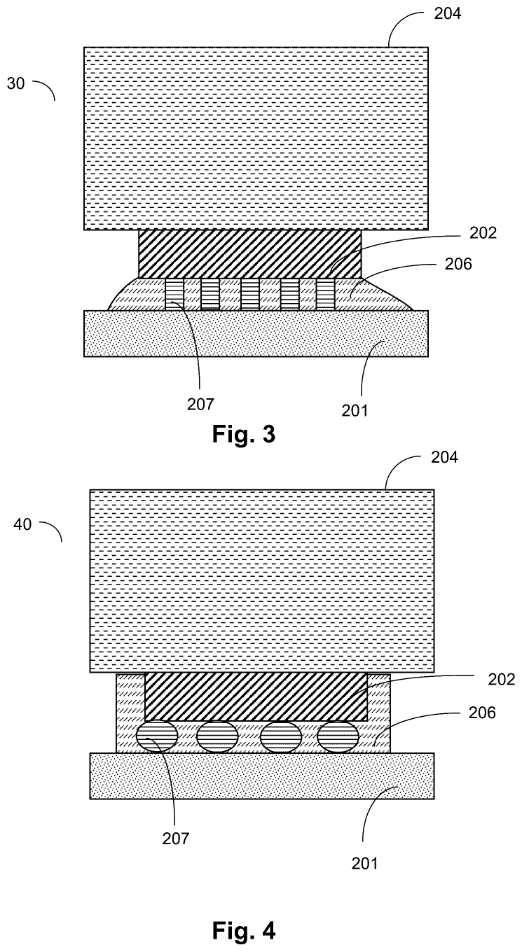

FIG. 4 shows another embodiment of an integrated package structure 40 with an inductor and an integrated circuit according to the present invention. The main distinction between this embodiment and that in FIG. 2 lies in the type of bonding material 207, designed to accommodate various process requirements and electrical connection characteristics.

In the embodiment shown in FIG. 4, the integrated circuit 202 is mounted on the substrate 201 using a flip-chip configuration. To achieve stable electrical and mechanical connections, the bonding material 207 adopts at least one solder ball instead of metal pillars or copper-copper bonding as shown in FIG. 2. Solder balls provide excellent conductivity and moderate elasticity, which helps buffer stress between the substrate 201 and the integrated circuit 202 while maintaining stable electrical connections, making it particularly suitable for applications requiring high reliability in packaging structures.

In this embodiment, the bonding material 207 between the integrated circuit 202 and the substrate 201 is covered by encapsulation material 206. The encapsulation material 206 can be applied using underfill or molding methods to protect the bonding area and enhance the overall stability of the package. The encapsulation material 206 fills the gaps between the integrated circuit 202 and the substrate 201, providing mechanical support and shielding the area from environmental factors.

Furthermore, the inductor 204 is positioned above the integrated circuit 202, and the bottom surface 204a of the inductor is directly connected to the exposed backside 202a of the integrated circuit, forming a thermal connection area. This direct connection design ensures an open thermal dissipation path and avoids the additional thermal resistance that may arise from the molding process.

The integrated package structure 40 in this embodiment uses solder balls as the bonding material 207, providing reliable electrical connections and improved mechanical stability, making it suitable for applications requiring durability and heat dissipation performance. This design balances electrical and thermal management needs while maintaining the compactness and stability of the package structure.

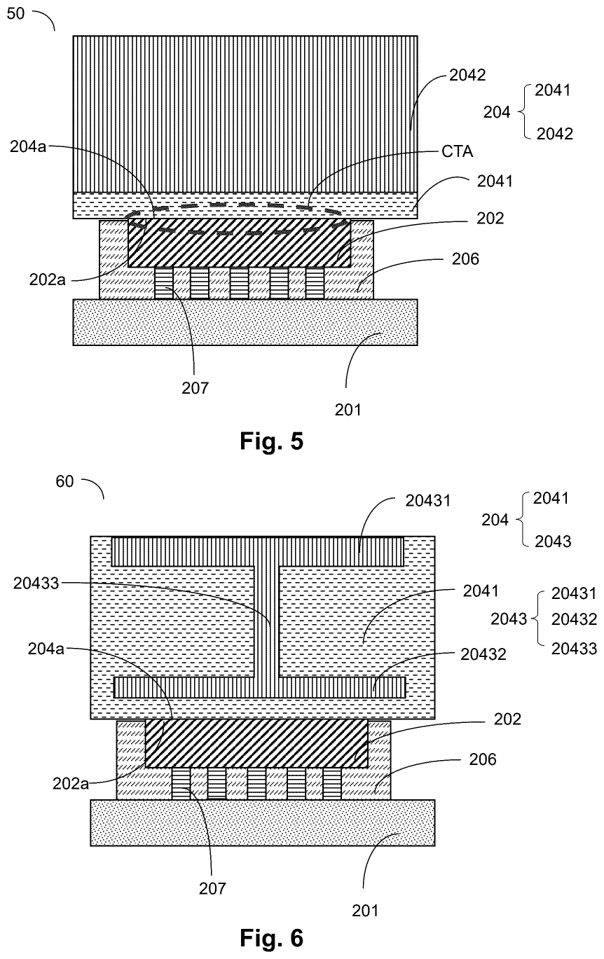

FIG. 5 illustrates another embodiment of an integrated package structure 50 with an inductor and an integrated circuit according to the present invention. The primary distinction between this embodiment and the embodiment in FIG. 2 lies in the design of the inductor 204. While the inductor 204 in FIG. 2 is of the exposed magnetic material type, the inductor 204 in FIG. 5 adopts a metal-encased configuration, further enhancing thermal and protective properties.

In the embodiment shown in FIG. 5, the inductor 204 comprises magnetic material 2041 and an encasing metal sheet 2042. The encasing metal sheet 2042 fully or partially encases the magnetic material 2041, providing additional mechanical protection and a more efficient thermal dissipation pathway. The bottom portion of the inductor 204 allows the backside 202a of the integrated circuit to connect partially with the magnetic material 2041 and partially with the encasing metal sheet 2042, balancing thermal and electrical isolation performance.

This design ensures that heat from the integrated circuit 202 is effectively conducted to both the magnetic material 2041 and the encasing metal sheet 2042 of the inductor 204, which further dissipates the heat. Depending on application requirements, the backside 202a of the integrated circuit may be connected exclusively to the magnetic material 2041 for electrical isolation or exclusively to the encasing metal sheet 2042 for enhanced thermal performance. This flexible design adapts to different application needs and optimizes the system's thermal management and electrical isolation requirements.

The integrated circuit 202 is mounted on the substrate 201 in a flip-chip configuration and electrically connected through bonding material 207. The bonding material 207 may include metal pillars, solder balls, or copper-copper bonding to provide stable electrical connections and mechanical support. In t s embodiment, encapsulation material 206 is used to protect the bonding area from environmental interference while maintaining mechanical stability between the integrated circuit 202 and the substrate 201.

Overall, the integrated package structure 50 enhances the effectiveness of the heat dissipation pathway through the metal-encased inductor design, improving the mechanical strength of the inductor 204. This design is suitable for applications requiring high power density and high reliability, ensuring excellent thermal conductivity and structural stability while providing design flexibility to meet various heat dissipation and electrical isolation needs.

FIG. 6 illustrates another embodiment of an integrated package structure 60 with an inductor and an integrated circuit according to the present invention. This embodiment differs from the embodiment in FIG. 2 in the structure of the inductor 204. While the inductor 204 in FIG. 2 is of the exposed magnetic material type, the inductor 204 in FIG. 6 adopts a metal-embedded design, further enhancing mechanical strength and thermal performance.

In this embodiment, the inductor 204 includes magnetic material 2041 and an embedded frame 2043. The frame 2043, made of a high thermal conductivity metal, provides an additional thermal conduction pathway. The frame 2043 structure comprises a top plate 20431, a bottom plate 20432, and at least one vertical frame 20433 between the top and bottom plates. This design forms a robust embedded frame structure, enabling the inductor 204 to maintain high inductance efficiency while improving thermal performance and stability.

The magnetic material 2041 provides the primary inductance and may cover the frame 2043 at the bottom of the inductor 204. In this embodiment, the metal portions of the frame 2043 effectively conduct heat from within the inductor 204, particularly through the top plate 20431, bottom plate 20432, and vertical frames 20433. The heat is efficiently dissipated into the surrounding environment. The bottom of the inductor 204 is designed so that the magnetic material 2041 directly connects with the backside 202a of the integrated circuit, forming a direct thermal conduction path to ensure that heat from the integrated circuit 202 is quickly transferred to the inductor 204 and dissipated.

The integrated circuit 202 is mounted on the substrate 201 in a flip-chip configuration and electrically connected through bonding material 207. The bonding material 207 may use metal pillars, solder balls, or copper-copper bonding to ensure electrical stability and mechanical support. In this embodiment, encapsulation material 206 fills the space between the integrated circuit 202 and the substrate 201 to protect the bonding area and enhance structural stability.

This embodiment of the integrated package structure 60, through the metal-embedded design of the inductor 204, not only improves the mechanical strength and thermal capacity of the inductor but also provides highly stable inductance characteristics. The embedded frame structure of the frame 2043 allows for effective heat dissipation while maintaining direct thermal connection between the magnetic material 2041 and the backside 202a of the integrated circuit, making it suitable for high power density applications with high thermal demands. This design ensures efficient heat dissipation, structural stability, and reliability in the package structure.

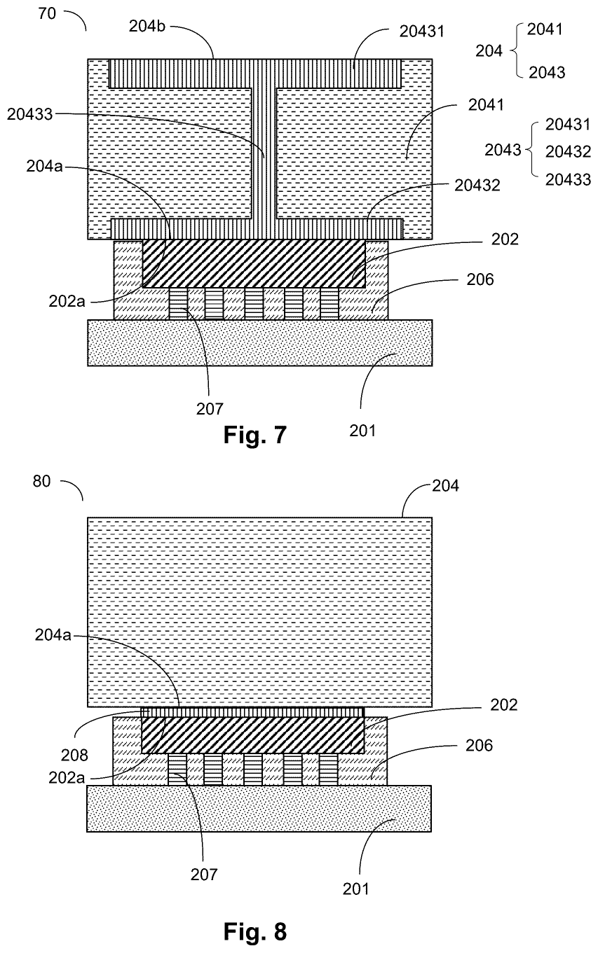

FIG. 7 shows another embodiment of an integrated package structure 70 with an inductor and an integrated circuit according to the present invention. This embodiment also adopts a metal-embedded design for the inductor 204, similar to the embodiment in FIG. 6, but differs in the details. In the embodiment shown in FIG. 7, the metal bottom plate 20432 of the inductor 204 is exposed at the bottom surface 204a of the inductor and directly connects to the backside 202a of the integrated circuit, forming a direct thermal conduction path. In contrast, in the embodiment of FIG. 6, the backside 202a of the integrated circuit is connected to the magnetic material 2041.

In this embodiment, the inductor 204 includes magnetic material 2041 and a frame 2043 made of a high thermal conductivity metal. The frame 2043 comprises a top plate 20431, a bottom plate 20432, and vertical frames 20433. This design ensures a stable structure that allows the inductor 204 to dissipate heat effectively. The frame 2043 is embedded within the magnetic material 2041, but in this embodiment, the bottom plate 20432 is selectively exposed at the bottom surface 204a of the inductor, connecting directly to the backside 202a of the integrated circuit, thereby enhancing thermal conduction.

Additionally, depending on application needs, the top plate 20431 of the inductor 204 can be selectively exposed or not exposed at the top surface 204b. If the top plate 20431 is exposed at the top surface 204b, the design further enhances heat dissipation, allowing heat to dissipate quickly into the surrounding environment. If the top plate 20431 is not exposed, it provides additional electromagnetic shielding, suitable for applications with higher electromagnetic interference (EMI) requirements.

The integrated circuit 202 is mounted on the substrate 201 in a flip-chip configuration and electrically connected through bonding material 207. The bonding material 207 may include metal pillars, solder balls, or copper-copper bonding, providing stable electrical and mechanical connections. Encapsulation material 206 fills the space between the integrated circuit 202 and the substrate 201, protecting the bonding area and enhancing structural stability.

Overall, this embodiment of the integrated package structure 70 improves thermal conduction performance by directly connecting the metal bottom plate 20432 of the inductor 204 to the backside 202a of the integrated circuit. The flexibility to choose whether to expose the top plate 20431 allows further optimization of either thermal dissipation or electromagnetic shielding, making this design suitable for applications requiring high thermal performance and high EMI resistance.

FIG. 8 illustrates another embodiment of an integrated package structure 80 with an inductor and an integrated circuit according to the present invention. This embodiment is similar to that shown in FIG. 2 but further reveals the thermal conduction connection method between the inductor 204 and the integrated circuit 202 to enhance heat dissipation performance.

In the embodiment shown in FIG. 8, a thermal interface material (TIM) 208 is placed between the bottom surface 204a of the inductor and the backside 202a of the integrated circuit. The thermal interface material 208 has excellent thermal conductivity, effectively filling gaps between the inductor 204 and the integrated circuit 202, thereby reducing thermal resistance and improving thermal conduction efficiency. This design ensures that heat generated by the integrated circuit 202 during operation is rapidly transferred through the thermal interface material 208 to the inductor 204 and then dissipated into the external environment.

In another embodiment, solder may be used instead of thermal interface material 208 to connect the bottom surface 204a of the inductor to the backside 202a of the integrated circuit. Solder provides even higher thermal conductivity, further improving thermal transfer performance. This design is suitable for applications with higher heat dissipation requirements and contributes to the stable operation of the integrated circuit 202.

As in other embodiments, the integrated circuit 202 is mounted on the substrate 201 in a flip-chip configuration and electrically connected through bonding material 207. The bonding material 207 may include metal pillars, solder balls, or copper-copper bonding, providing stable electrical and mechanical connections. Encapsulation material 206 fills the space between the integrated circuit 202 and the substrate 201, protecting the bonding area and enhancing structural stability.

This embodiment of the integrated package structure 80 enhances overall thermal conduction efficiency through the use of thermal interface material 208 or solder between the inductor 204 and the integrated circuit 202 while maintaining stable electrical and mechanical connections. This structure is well-suited for high-power density electronic applications, effectively improving thermal performance and ensuring the stability and reliability of the integrated circuit.

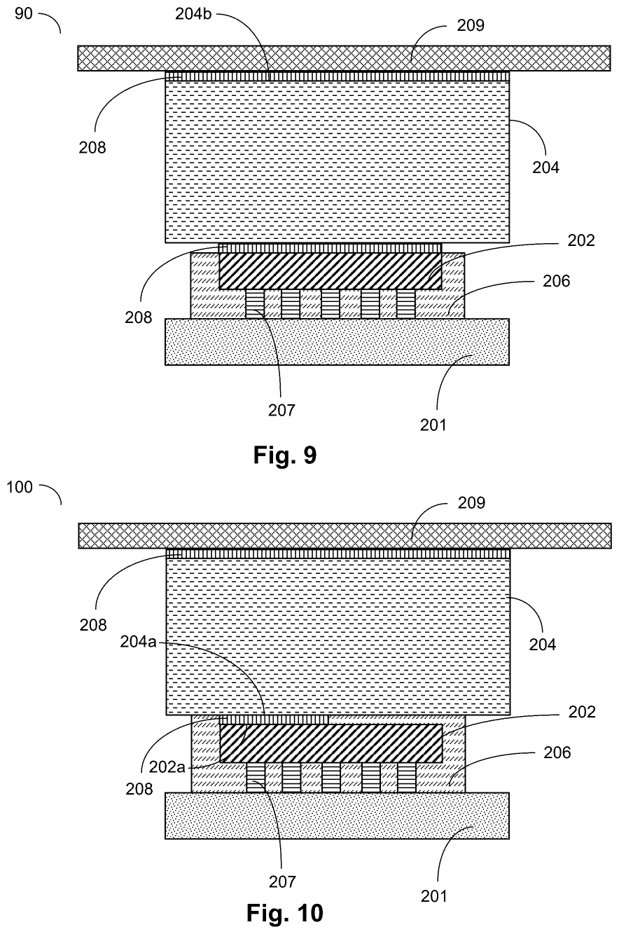

FIG. 9 depicts another embodiment of an integrated package structure 90 with an inductor and an integrated circuit according to the present invention. This embodiment builds upon the design in FIG. 8, introducing further improvements to enhance overall thermal performance. While FIG. 8 employs thermal interface material 208 between the bottom surface 204a of the inductor and the backside 202a of the integrated circuit, FIG. 9 adds a metal plate 209 on top of the inductor 204 to further optimize the thermal dissipation pathway.

In this embodiment, the metal plate 209 is placed above the inductor 204 and connected to the top surface 204b of the inductor through another layer of thermal interface material 208. The thermal interface material 208 has excellent thermal conductivity, filling the gaps between the metal plate 209 and the top surface 204b of the inductor, reducing thermal resistance, and ensuring efficient thermal transfer from the inductor 204 to the metal plate 209 and then into the surrounding environment.

In another embodiment, solder may be used instead of thermal interface material 208 to connect the top surface 204b of the inductor to the metal plate 209. Solder's higher thermal conductivity further enhances thermal transfer, making this design ideal for applications requiring superior heat dissipation. This ensures the stable operation of the inductor 204 under high power density conditions, preventing overheating issues.

The integrated circuit 202 is mounted on the substrate 201 in a flip-chip configuration and electrically connected through bonding material 207. The bonding material 207 may include metal pillars, solder balls, or copper-copper bonding, ensuring stable electrical and mechanical connections. Encapsulation material 206 fills the space between the integrated circuit 202 and the substrate 201, protecting the bonding area and enhancing structural stability.

Overall, embodiment of the integrated package structure 90 optimizes the thermal dissipation pathway by adding a metal plate 209 above the inductor 204 and using thermal interface material 208 for connection. This design is particularly suitable for high-power density and high thermal dissipation electronic applications, significantly improving overall thermal performance and ensuring the stability and reliability of the integrated circuit and inductor under high-power operating conditions.

FIG. 10 illustrates another embodiment of an integrated package structure 100 with an inductor and an integrated circuit according to the present invention. This embodiment builds upon the design in FIG. 9 and focuses on the specific exposure range of the backside 202a of the integrated circuit and its connection method with the inductor 204 to achieve an optimized balance between thermal conduction and structural stability.

In this embodiment, the backside 202a of the integrated circuit is not fully exposed but is only partially exposed to connect with the bottom surface 204a of the inductor via a thermal interface material (TIM) 208. This partial exposure design allows only the necessary portions of the integrated circuit's backside 202a to be uncovered for thermal conduction, while the remaining areas are protected by encapsulation material 206. This approach ensures an optimized balance between heat transfer efficiency and structural integrity.

The thermal interface material 208, placed between the exposed portion of the backside 202a of the integrated circuit and the bottom surface 204a of the inductor, has excellent thermal conductivity. It effectively fills the gaps in the contact area, reducing thermal resistance and enabling efficient heat transfer. This design ensures that heat generated by the integrated circuit during operation is rapidly transferred to the inductor and then dissipated into the surrounding environment.

Additionally, in this embodiment, a metal plate 209 is placed above the inductor 204 and connected to the top surface 204b of the inductor through another layer of thermal interface material 208. This second layer of thermal interface material further enhances the heat dissipation pathway, allowing heat from the inductor to transfer efficiently to the metal plate and dissipate into the environment, improving the overall thermal performance of the package structure.

The integrated circuit 202 is mounted on the substrate 201 in a flip-chip configuration and electrically connected through bonding material 207. The bonding material 207, which can include metal pillars, solder balls, or copper-copper bonding, provides stable electrical connections and mechanical support. The encapsulation material 206 fills the space between the integrated circuit 202 and the substrate 201, protecting the bonding area and improving structural stability.

In summary, this embodiment of the integrated package structure 100 achieves superior thermal performance through the partial exposure of the integrated circuit's backside 202a and the use of thermal interface material 208 for selective filling. The inclusion of the metal plate 209 further enhances heat dissipation, making the design suitable for high-power density applications with strict requirements for heat management and reliability.

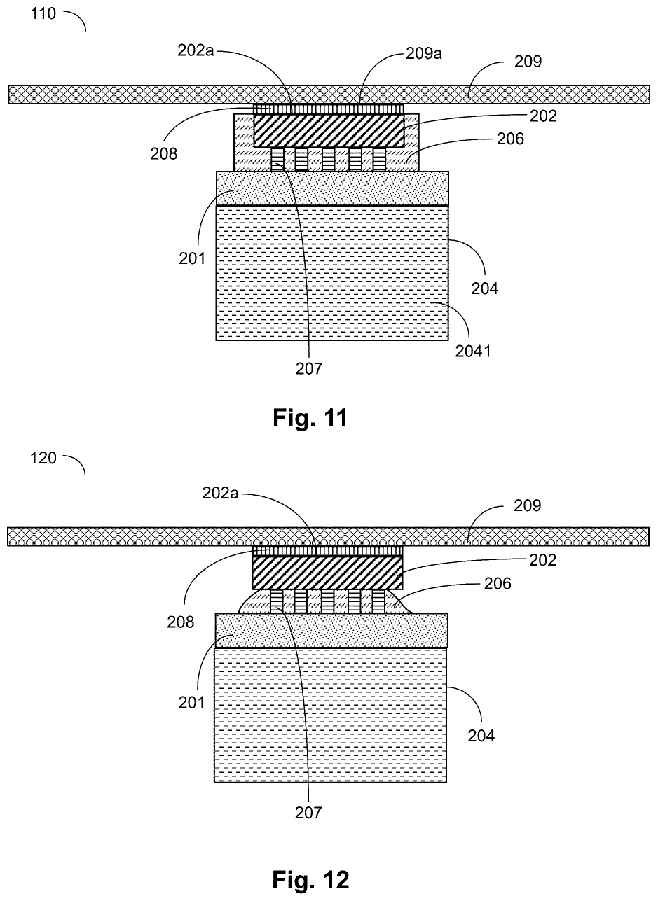

FIG. 11 shows another embodiment of an integrated package structure 110 with an inductor and an integrated circuit according to the present invention. Similar to previous embodiments, this structure comprises a substrate 201, an integrated circuit 202, and an inductor 204. The substrate 201 provides a predetermined circuit layout to support and connect various electronic components and may be a printed circuit board (PCB) or lead frame with electrical signal transmission functionality.

The integrated circuit 202 is mounted on the substrate 201 in a flip-chip configuration and electrically connected through bonding material 207. Encapsulation material 206 protects the bonding material 207, shielding the electrical connections from environmental interference. However, the backside 202a of the integrated circuit is at least partially exposed to facilitate heat dissipation.

A metal plate 209 is placed above the integrated circuit 202, with its lower surface 209a connecting to the exposed backside 202a of the integrated circuit. The connection area CTA between the metal plate 209 and the backside 202a includes portions that are free of encapsulation material to ensure optimal thermal conduction.

According to the present invention, this embodiment of the integrated packaging structure 110 not only enhances the heat dissipation efficiency of the integrated circuit (IC) 202 but also reduces the overall space required. The encapsulating material 206 is applied only to protect the electrical connections on the sides and bottom of the IC 202, leaving the backside of the IC uncovered. This ensures an unobstructed heat dissipation path and reduces thermal resistance caused by thermal interface materials or thermal paste.

As shown in FIG. 11, in one embodiment, the integrated packaging structure 110 features improved heat dissipation characteristics by enhancing the connection and thermal performance between the metal plate 209 and the IC 202 through specific technical features. For example, the backside 202a of the IC 202 can be configured without backside metallization (non-BSM) or with backside metallization (BSM), depending on thermal and electrical requirements. This selective design allows the IC 202's backside 202a to be treated according to application needs, further optimizing thermal and electrical performance.

In one embodiment, the magnetic material inside the inductor 204 may be composed of ceramic magnetic materials or metallic soft magnetic materials. Specifically, the magnetic materials can include ceramic materials such as nickel-zinc ferrite, manganese-zinc ferrite, or magnesium-copper-zinc ferrite, or metallic soft magnetic materials such as carbonyl iron powder, iron-nickel alloys, iron-silicon alloys, iron-silicon-aluminum alloys, iron-silicon-chromium alloys, or amorphous alloys. These materials have high thermal conductivity, which improves the heat dissipation efficiency of the inductor 204, while also possessing insulating properties to protect the IC 202 from electrical interference.

The connection structures 207 between the IC 202 and the substrate 201 may include at least one metal pillar, at least one solder ball, or at least one copper-to-copper bond. These connection methods provide stable electrical and mechanical connections between the IC 202 and the substrate 201, balancing the demands for electrical connection strength and thermal performance in the packaging structure. This design ensures a reliable connection and achieves good electrical conductivity and heat dissipation.

The inductor 204 can adopt different structural configurations, such as exposed magnetic material, metal-encased, or metal-embedded designs. In the embodiment shown in FIG. 11, the inductor 204 uses an exposed magnetic material structure. The inductor 204 can also be configured as a metal-encased or metal-embedded structure, as shown in FIGS. 5 and 6, respectively, which are not further described here.

In one embodiment, the bottom surface 209a of the metal plate can be connected to the backside 202a of the IC 202 through thermal interface material (TIM) 208 or solder. The TIM 208 provides an efficient thermal conduction path while ensuring a stable connection between the metal plate 209 and the IC 202. This reduces thermal resistance and enhances heat dissipation efficiency. This design achieves optimal thermal performance while maintaining stable connections.

In one embodiment, the backside 202a of the IC 202 can be partially or fully exposed to facilitate connection with the bottom surface 209a of the metal plate. By exposing the IC's backside 202a, the invention effectively enhances heat dissipation efficiency and reduces thermal resistance introduced by encapsulation or other materials. This design ensures an unobstructed heat dissipation path and significantly improves the IC's performance in high heat dissipation applications.

FIG. 12 illustrates another embodiment of the integrated packaging structure 120 according to the present invention. The main difference from the embodiment in FIG. 11 lies in the packaging method for the IC 202.

In the embodiment shown in FIG. 12, the IC 202 is mounted on the substrate 201 using a flip-chip method, providing stable electrical connections and reducing connection impedance. Unlike FIG. 11, this embodiment uses underfill material 206 instead of molding. The underfill material fills the gaps between the IC 202 and the substrate 201, enhancing mechanical strength and protection while leaving the IC's backside 202a uncovered for heat dissipation.

In this embodiment, underfill material provides side and bottom protection for the IC 202 while allowing its backside to remain exposed, maximizing heat dissipation efficiency. This design further enhances the heat dissipation performance of the integrated packaging structure 120 while reducing the space occupied by molding, resulting in a more compact and efficient structure. This configuration is advantageous for applications requiring high power density and miniaturization.

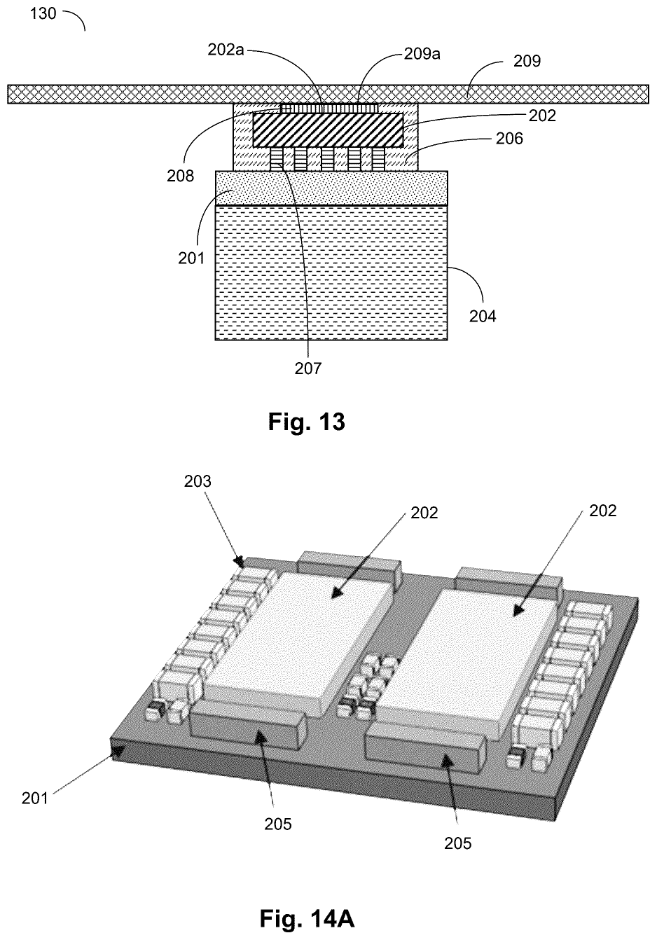

FIG. 13 illustrates another embodiment of the integrated packaging structure 130 according to the present invention. Compared to the embodiment in FIG. 11, the main difference lies in the extent of exposure of the IC's backside 202a and its connection with the metal plate 209.

In the embodiment shown in FIG. 13, the backside 202a of the IC 202 is only partially exposed and connected to the bottom surface 209a of the metal plate through TIM 208. This selective exposure allows the IC's backside 202a to be exposed only where heat conduction is required, while other areas are protected by the encapsulation material 206, achieving a balance between thermal performance and structural stability.

The TIM 208 fills the exposed portion of the IC's backside 202a and the bottom surface 204a of the inductor 204, providing excellent thermal conductivity. It effectively reduces contact thermal resistance, allowing the heat generated by the IC 202 to be quickly transferred to the inductor 204 and further dissipated into the environment. In this embodiment, the TIM 208 is selectively applied only to the exposed portion of the IC's backside 202a, optimizing heat dissipation efficiency while protecting other regions of the IC from environmental impacts.

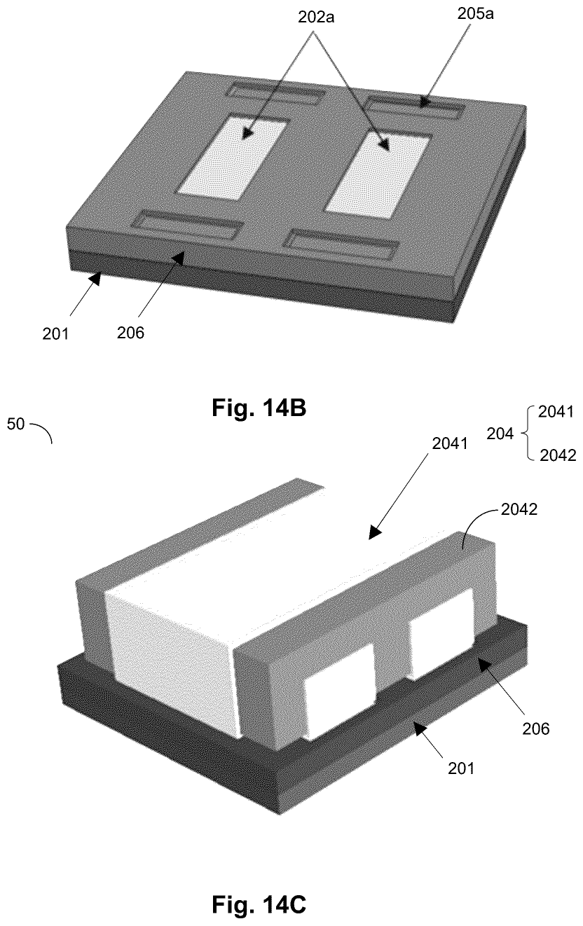

FIGS. 14A, 14B, and 14C illustrate the manufacturing process for the integrated packaging structure 50 with an inductor and IC, as described in FIG. 5. These steps provide details on the fabrication and assembly of the structure.

First, as shown in FIG. 14A and also referenced in FIG. 5, the process begins by placing the IC 202 on the substrate 201 using a flip-chip bonding method. As illustrated in FIG. 5, connection structures 207 join the IC 202 and substrate 201. The substrate 201 has a predefined circuit layout for carrying and connecting other electronic components, such as the passive components 203 shown in FIG. 14A. The substrate 201 can be a printed circuit board (PCB) or a lead frame, facilitating electrical signal transmission and connection to the IC 202. Additionally, spacer pillars 205 (e.g., copper pillars) can be added to elevate the connection height between the inductor 204 and the substrate 201. This is particularly useful when the inductor's leads are not long enough. Spacer pillars 205 are optional components and can be included depending on specific design requirements.

Next, as shown in FIG. 14B and also referenced in FIG. 5, after molding the IC 202, its backside 202a is polished to expose the backside 202a and the top surface 205a of the spacer pillars 205. This step can use molding or underfill methods, aiming to partially expose the backside 202a of the IC 202 to enhance thermal conductivity. Meanwhile, the connection structures 207 linking the IC 202 and substrate 201 are protected by the encapsulating material 206 to safeguard the electrical connection area from environmental interference. Encapsulating material 206 can be applied through underfill or molding methods, ensuring that at least part of the IC's backside 202a remains exposed for subsequent thermal management.

Finally, as shown in FIG. 14C and also referenced in FIG. 5, the inductor 204 is placed above the IC 202 to form the integrated packaging structure. The bottom surface 204a of the inductor 204 is connected to the backside 202a of the IC 202 in the connection area CTA. In this area, at least part of the encapsulating material is absent, ensuring the effectiveness of the thermal conduction path. The inductor 204 contains magnetic material 2041 and a metal covering 2042. In this embodiment, the inductor 204 adopts a metal-covered design, where the metal covering 2042 connects to the backside 202a of the IC 202. This design enhances thermal conduction, further improving the IC's heat dissipation performance.

In other embodiments, the inductor 204 can take the form of the exposed magnetic material design shown in FIG. 2 or the metal-embedded design shown in FIG. 6, to meet different thermal and electromagnetic interference requirements. This embodiment ensures that the integrated packaging structure 50 provides efficient thermal dissipation and stable electrical connections, making it particularly suitable for high-power-density electronic applications.

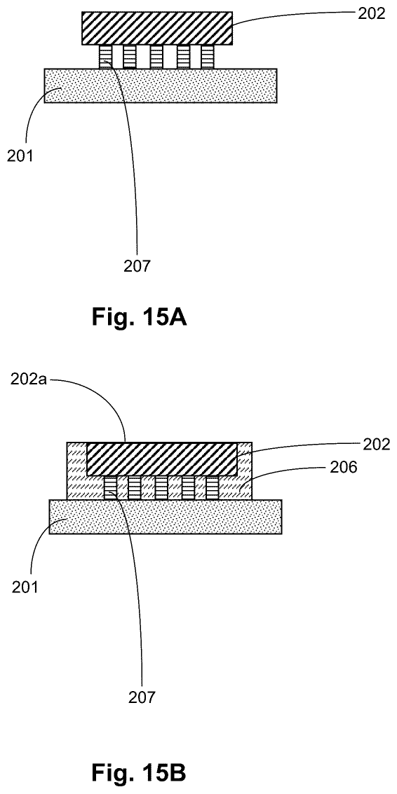

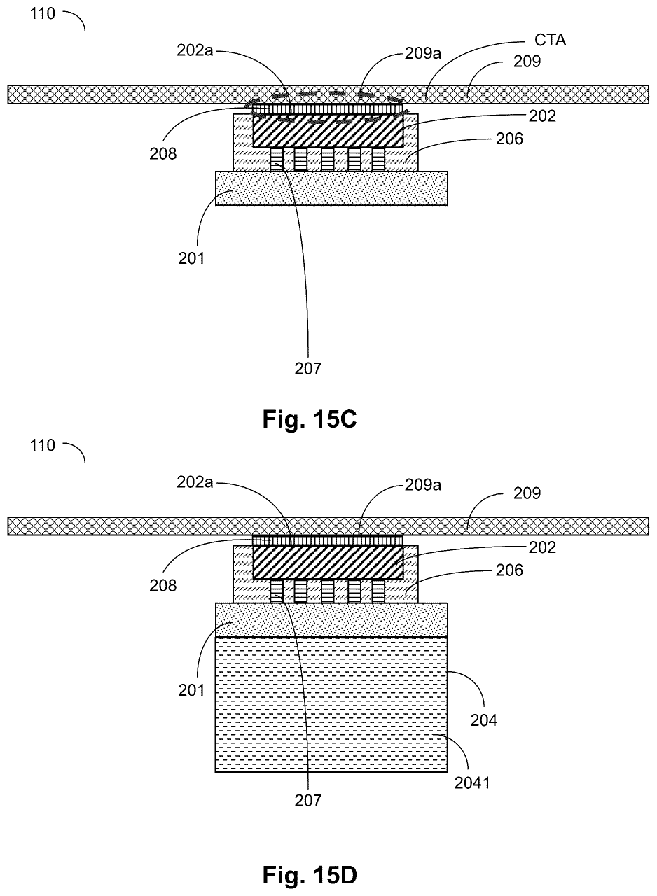

FIGS. 15A, 15B, and 15C illustrate the manufacturing process for the integrated packaging structure 110 with an inductor and IC, as described in FIG. 11. These steps detail the assembly process and associated features.

First, as shown in FIG. 15A and also referenced in FIG. 11, the process begins by placing the IC 202 on the substrate 201 using a flip-chip bonding method. The connection structures 207 connect the IC 202 and substrate 201. The substrate 201 includes a predefined circuit layout for carrying and connecting other electronic components. The substrate 201 can be a PCB or a lead frame, providing electrical signal transmission and connection to the IC 202.

Next, as shown in FIG. 15B and also referenced in FIG. 11, after molding the IC 202, its backside 202a is polished to expose the backside 202a. This step can use molding or underfill methods, aiming to partially expose the backside 202a of the IC 202 to enhance thermal conductivity. Meanwhile, the connection structures 207 linking the IC 202 and substrate 201 are protected by the encapsulating material 206, safeguarding the electrical connection area from environmental interference. The encapsulating material 206 can be applied through underfill or molding methods, ensuring that at least part of the IC's backside 202a remains exposed for subsequent thermal management.

Next, as shown in FIG. 15C and also referenced in FIG. 11, the metal plate 209 is placed above the IC 202. The bottom surface 209a of the metal plate is connected to the backside 202a of the IC 204, forming the connection area CTA. In this area, at least part of the encapsulating material is absent to optimize thermal performance.

Then, as shown in FIG. 15D and also referenced in FIG. 11, the inductor 204 is placed beneath the substrate 201 and connected to it. The inductor 204 includes magnetic material 2041. In this embodiment, the inductor 204 adopts an exposed magnetic material design.

In other embodiments, the inductor 204 can take the form of the metal-covered design shown in FIG. 5 or the metal-embedded design shown in FIG. 6, to meet different thermal and electromagnetic interference requirements. This embodiment ensures that the integrated packaging structure 110 provides efficient thermal dissipation and stable electrical connections, making it particularly suitable for high-power-density electronic applications.

The present invention has been described in considerable detail with reference to certain preferred embodiments thereof. It should be understood that the description is for illustrative purpose, not for limiting the broadest scope of the present invention. Those skilled in this art can readily conceive variations and modifications within the spirit of the present invention. The various embodiments described above are not limited to being used alone; two embodiments may be used in combination, or a part of one embodiment may be used in another embodiment. For example, when integrated circuits are placed on the lead frame in quantities different from those shown in the figures, when passive components are arranged in a different sequence, or when the shapes of the electronic components differ from those illustrated, etc. Therefore, in the same spirit of the present invention, those skilled in the art can think of various equivalent variations and various combinations, and there are many combinations thereof, and the description will not be repeated here. The scope of the present invention should include what are defined in the claims and the equivalents.

What is claimed is:

1. An integrated package structure with an inductor and an integrated circuit, comprising:
a substrate having a predetermined circuit layout;
an integrated circuit positioned on the substrate, wherein the integrated circuit is joined to the substrate in a flip-chip configuration, and a joint between the integrated circuit and the substrate is encapsulated by a covering material, with a back surface of the integrated circuit exposed; and
an inductor positioned above the integrated circuit, wherein a lower surface of the inductor is connected to the back surface of the integrated circuit, forming a connection area, wherein at least a portion of the connection area is free from encapsulation material.

2. The integrated package structure of claim 1, wherein the integrated circuit, after molding, has its back surface exposed by grinding the encapsulation material on the back surface.

3. The integrated package structure of claim 1, wherein the integrated circuit, after underfilling and without molding, has its back surface exposed.

4. The integrated package structure claim 1, wherein the back surface of the integrated circuit is non-backside metal (non-BSM) or comprises backside metal (BSM).

5. The integrated package structure of claim 1, wherein the substrate includes a lead frame or a printed circuit board (PCB).

6. The integrated package structure of claim 1, wherein a magnetic material providing inductance comprises ceramic magnetic material or soft magnetic metal material, wherein the ceramic magnetic material includes nickel-zinc ferrite, manganese-zinc ferrite, or magnesium-copper-zinc ferrite, and the soft magnetic metal material includes carbonyl iron powder, iron-nickel alloy, iron-silicon alloy, iron-silicon-aluminum alloy, iron-silicon-chromium alloy, or amorphous alloy.

7. The integrated package structure of claim 1, wherein the joint includes at least one metal pillar, at least one solder ball, or at least one copper-copper bond.

8. The integrated package structure of claim 1, wherein the inductor is in a form selected from an exposed magnetic material or a metal-embedded configuration.

9. The integrated package structure of claim 8, wherein, when the inductor is in the form of an exposed magnetic material, the magnetic material providing inductance is connected to the back surface of the integrated circuit.

10. The integrated package structure of claim 8, wherein, when the inductor is in the form of a metal-embedded configuration, a magnetic material or a framework on the outer side of the inductor is connected to the back surface of the integrated circuit.

11. The integrated package structure of claim 1, wherein the lower surface of the inductor is connected to the back surface of the integrated circuit through a thermal interface material (TIM) or a solder.

12. The integrated package structure of claim 1, further comprising a metal plate positioned above the inductor, wherein the metal plate is connected to an upper surface of the inductor through a thermal interface material or solder.

13. The integrated package structure of claim 1, wherein the back surface of the integrated circuit is partially or fully exposed and connected to the lower surface of the inductor.

14. An integrated package structure with an inductor and an integrated circuit, comprising:
a substrate having a predetermined circuit layout;
an integrated circuit positioned on the substrate, wherein the integrated circuit is joined to the substrate in a flip-chip configuration, and a joint between the integrated circuit and the substrate is encapsulated by a covering material, with a back surface of the integrated circuit exposed;
a metal plate positioned above the integrated circuit, wherein a lower surface of the metal plate is connected to the back surface of the integrated circuit, forming a connection area, wherein at least a portion of the connection area is free from encapsulation material; and
an inductor positioned below the substrate and connected thereto.

15. The integrated package structure of claim 14, wherein the covering material encapsulating the joint is formed using underfilling or molding.

16. The integrated package structure of claim 15, wherein, after molding, the back surface of the integrated circuit is exposed by grinding the encapsulation material.

17. The integrated package structure of claim 15, wherein the integrated circuit, after underfilling and without molding, has its back surface exposed.

18. The integrated package structure of claim 14, wherein the back surface of the integrated circuit is non-backside metal (non-BSM) or comprises backside metal (BSM).

19. The integrated package structure of claim 14, wherein the substrate includes a lead frame or a printed circuit board (PCB).

20. The integrated package structure of claim 14, wherein the magnetic material providing inductance comprises ceramic magnetic material or soft magnetic metal material, wherein the ceramic magnetic material includes nickel-zinc ferrite, manganese-zinc ferrite, or magnesium-copper-zinc ferrite, and the soft magnetic metal material includes carbonyl iron powder, iron-nickel alloy, iron-silicon alloy, iron-silicon-aluminum alloy, iron-silicon-chromium alloy, or amorphous alloy.

21. The integrated package structure of claim 14, wherein the joint includes at least one metal pillar, at least one solder ball, or at least one copper-copper bond.

22. The integrated package structure of claim 14, wherein the inductor is in a form selected from an exposed magnetic material or a metal-embedded configuration.

23. The integrated package structure of claim 14, wherein a lower surface of the metal plate is connected to the back surface of the integrated circuit through a thermal interface material (TIM).

24. The integrated package structure of claim 14, wherein the back surface of the integrated circuit is partially or fully exposed and connected to the lower surface of the metal plate.

25. A method of manufacturing an integrated package structure with an inductor and an integrated circuit, comprising:
providing an integrated circuit;
positioning the integrated circuit on a substrate and joining the integrated circuit to the substrate in a flip-chip configuration;
after molding, grinding the encapsulation material on a back surface of the integrated circuit, or performing underfilling without molding to expose a back surface of the integrated circuit; and
positioning an inductor above the integrated circuit, wherein a lower surface of the inductor is connected to the back surface of the integrated circuit, forming a connection area, wherein at least a portion of the connection area is free from encapsulation material.

26. The method of manufacturing an integrated package structure of claim 25, wherein the inductor is in a form selected from an exposed magnetic material or a metal-embedded configuration.

27. The method of manufacturing an integrated package structure with an inductor and an integrated circuit of claim 26, wherein, when the inductor is in the form of an exposed magnetic material, a magnetic material providing inductance is connected to the back surface of the integrated circuit.

28. The method of manufacturing an integrated package structure of claim 26, wherein, when the inductor is in the form of a metal-embedded configuration, an outer-side magnetic material or framework of the inductor is connected to the back surface of the integrated circuit.

29. A method of manufacturing an integrated package structure with an inductor and an integrated circuit, comprising:
providing an integrated circuit;
positioning the integrated circuit on a substrate and joining the integrated circuit to the substrate in a flip-chip configuration;
after molding, grinding the encapsulation material on a back surface of the integrated circuit, or performing underfilling without molding to expose a back surface of the integrated circuit;
positioning a metal plate above the integrated circuit, wherein a lower surface of the metal plate is connected to the back surface of the integrated circuit, forming a connection area, wherein at least a portion of the connection area is free from encapsulation material; and
positioning an inductor below the substrate and connecting it to the substrate.

30. The method of manufacturing an integrated package structure of claim 29, wherein the inductor is in a form selected from an exposed magnetic material or a metal-embedded configuration.

31. The method of manufacturing an integrated package structure of claim 29, wherein the lower surface of the metal plate is connected to the back surface of the integrated circuit through a thermal interface material (TIM).
